(19) United States
(12) Patent Application Publication
(10) Pub. No.: US 2007/0029941 A1
(43) Pub. Date: Feb. 8, 2007

(54) Organic electroluminescence display apparatus

(76) Inventors: Naoyuki Ito, Furano (JP); Kanae Yamanaka, Toyonaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/476,723

(22) Filed: Jun. 29, 2006

(30) Foreign Application Priority Data
Jun. 29, 2005 (JP) 2005-189703

(51) Int. Cl. G09G 3/10

(52) U.S. Cl. 315/169.3; 315/169.2; 313/503

(57) ABSTRACT

There is provided a high-definition and small-parallax active-driving organic EL display apparatus capable of avoiding complication of manufacturing processes and skyrocketing in component and material expenses. A plurality of organic EL elements BU, GU, and RU are multi-layered in a single subpixel area. All of active elements (i.e., thin-film transistors TFTs) to be connected to the multi-layered organic EL elements are formed between an insulating substrate SUB and the layer of the organic EL element BU which is the most proximate to this insulating substrate. This configuration makes it possible to avoid the second-layer or upper organic EL elements GU and RU from being damaged by the high-heat processing in the manufacturing processes. Accordingly, it becomes possible to implement long life-expectancy of the organic EL display apparatus. Also, inter-layer spacing between the organic EL elements can be made narrower. Consequently, it becomes possible to make the parallax exceedingly smaller.

### INCORPORATION BY REFERENCE

The present application claims priority from Japanese application JP2005-189703 filed on Jun. 29, 2005, the content of which is hereby incorporated by reference into this application.

### BACKGROUND OF THE INVENTION

1. Field of the Invention

The present invention relates to an organic EL display apparatus. More preferably, it relates to an active-matrix organic EL display apparatus where a plurality of organic EL elements are multi-layered on an insulating substrate.

2. Description of the Related Art

As flat-panel display apparatuses, such display apparatuses as liquid-crystal display apparatuses (LCD), plasma display apparatuses (PDP), field emission display apparatuses (FED), and organic EL display apparatuses (OLED) have been already at the practical-commercialization stage, or are now at the practical-commercialization research stage. Of these display apparatuses, the organic EL display apparatuses in particular are exceedingly promising display apparatuses as a typical example of thin-type and light-weighted spontaneous light-emitting display apparatuses in the near future.

The organic EL display apparatuses are classified into the so-called bottom-emission type and the so-called top-emission type. In the bottom-emission organic EL display apparatus, each organic EL element is configured by a light-emitting mechanism which is formed by multi-layering the following configuration components sequentially on an insulating substrate which is preferably a glass substrate: A transparent electrode (such as ITO) as a first electrode or one of electrodes, an organic multi-layer film (which is also referred to as an organic light-emitting layer) for emitting light by application of an electric field thereto, a reflection-property metal electrode as a second electrode or the other electrode. These organic EL elements are arranged in large numbers in a matrix-like manner. Then, another substrate which is referred to as a sealing can is provided such that the sealing can covers these multi-layer structures, thereby shielding the above-described light-emitting structure from the external atmosphere. Moreover, for example, the transparent electrode is employed as an anode, and the metal electrode is employed as a cathode, then applying the electric field therebetween. This electric-field application injects carriers (i.e., electrons and positive holes) into the organic multi-layer film, thereby causing the organic multi-layer film to emit the light. This light emission is configured to be emitted out to the outside from the glass-substrate side.

Meanwhile, in the top-emission organic EL display apparatus, the metal electrode having the reflection property is selected as the above-described one electrode, and the transparent electrode such as ITO is selected as the above-described other electrode, then applying the electric field therebetween. This electric-field application causes the organic multi-layer film to emit the light. This light emission is configured to be emitted out to the outside from the other-electrode side. In the top-emission display apparatus, a transparent plate, which is preferably a glass plate, is used as the sealing can in the bottom-emission display apparatus.

In JP-A-09-82472, an organic EL display apparatus is disclosed where two insulating substrates, on which passive-driving organic EL elements are on-board, are pasted in the direction in which the on-board surfaces of the organic EL elements are opposed to each other. In this organic EL display apparatus, two red (R) and green (G) unit pixels (i.e., subpixels) and one blue (B) unit pixel are formed on one of the two insulating substrates in a manner of being overlapped with each other via space. Also, in JP-A-10-503878, a passive-matrix organic EL display apparatus is disclosed where a plurality of organic EL elements are multi-layered on an insulating substrate within one unit pixel.

In the technology disclosed in JP-A-09-82472, the one-layer organic EL elements are formed on the one-side surface of each of the two insulating substrates. Then, the organic-EL-elements formation surface sides of both insulating substrates are multi-layered in the manner of being opposed to each other, thereby forming the two-layer organic EL elements. This formation method requires setting of complicated manufacturing processes where the light-emitting layer will be formed on one of the two insulating substrates in such a manner that the light-emitting layer is divided into two areas for each color. This requirement further requires that the organic EL elements be multi-layered in the number of the layers which is the same as the number of the colors.

In JP-A-09-82472, however, the one-layer organic EL elements have been formed on the one-side surface of each of the two insulating substrates. As a result, when trying to reform the organic EL elements into three-layer organic EL elements on the basis of the above-described technological idea, it turns out that one more piece of insulating substrate on the one-side surface of which the one-layer organic EL elements are formed will be added thereto, or that the organic EL elements will be on-board on either of the surfaces of the two insulating substrates. However, when the light is extracted via the insulating substrate, thickness of the insulating substrate causes a large parallax to occur.

In JP-A-10-503878, the structure is disclosed where the plurality of organic EL elements are multi-layered on the one insulating substrate. Here, taking both JP-A-09-82472 and JP-A-10-503878 into consideration makes it possible to configure the organic EL display apparatus where the plurality of organic EL elements for emitting different colors are multi-layered. Neither disclosure nor suggestion, however, has been made concerning a technological idea of the active driving for the plurality of organic EL elements which are multi-layered in this way.

In FIG. 2 in JP-A-10-503878, a structure is disclosed where data lines and scanning lines are extracted for each of the layers where the plurality of multi-layered organic EL elements are formed. Namely, the wiring is so configured as to be closed in each layer. If it is wished that the combination of JP-A-10-503878 and a general active-driving organic EL display apparatus is to be implemented, the way of thinking disclosed in JP-A-10-503878 should be regarded as its presumption. Accordingly, it turns out that active elements including components such as semiconductor layers and gate insulating films will be formed for each layer. If, however, it is wished that such a structure is to be implemented, a high-heat process at the time of forming the active elements in the second layer or thereafter causes damage to occur in the first-layer organic EL elements. This damage lowers life-expectancy of the organic EL display apparatus.

Also, in JP-A-10-503878, a structure is disclosed where the wirings are routed in the respective layers, and where the respective layers are shifted at circumferential portions of the insulating substrates thereby to expose terminals. In this method, however, there occurs a necessity that step-heights to be used for the terminals be ensured in large areas at the circumferential portions. This necessity makes it difficult to satisfy the request for narrow-frame implementation. Also, in addition thereto, there occurs a necessity for taking advantage of the junction technologies for surmounting the above-described step-heights, such as FPC (flexible circuit substrate) and WB (wire bonding). This necessity results in serious demerits in the aspects of manufacturing-processes number and component and material expenses.

Also, in recent years, the rapid-paced prevalence of mobile telephones has aroused tremendous demand in the mobile-telephone market for display apparatuses which allow front-and-back double-side display of main screen and sub screen. This tremendous demand has further aroused a desire for even-higher performance implementation and even-lighter weight implementation of the display apparatuses. Also, not limited to the mobile telephones, in a display apparatus (mobile viewer) as well which is mounted on mobile appliances such as a multimedia player, the demand for the thin-type and double-side display apparatuses of this type tends to increase. Accordingly, it is conceivable that the request for the thin-type implementation and light-weight implementation of the display apparatus will also become stronger and stronger.

Of the existing double-side display apparatuses, the most prevalent ones are of a type where two pieces of display panels are located in a back-to-back manner. As a result, a limit exists to the thin-type implementation of each display panel itself. This limit makes it difficult to accomplish the thin-type implementation and light-weight implementation of the entire double-side display apparatus.

It is an object of the present invention to provide a long life-expectancy and active-driving organic EL display apparatus.

It is another object of the present invention to provide a high-definition and small-parallax active-driving organic EL display apparatus which is capable of avoiding complication of the manufacturing processes and skyrocketing in the component and material expenses.

Moreover, it is still another object of the present invention to provide a double-side organic EL display apparatus which allows accomplishment of the thin-type implementation and light-weight implementation thereof.

### SUMMARY OF THE INVENTION

The present invention includes a plurality of units and methods for accomplishing the above-described object. The outlines of the representative units and methods to be described herein are as follows:

Namely, in the present invention, all the active elements to be connected to the plurality of multi-layered organic EL elements are formed between the insulating substrate and the first layer of the organic EL elements which is the most proximate to this insulating substrate. This configuration makes it possible to avoid the second-layer or upper organic EL elements from being damaged by the high-heat processing for the active elements in the manufacturing processes. Accordingly, it becomes possible to implement the long life-expectancy of the organic EL display apparatus. Also, since the active elements need not be located between the organic EL elements, inter-layer spacing between the organic EL elements arranged in the multi-layer direction can be made narrower. Consequently, it becomes possible to make the parallax exceedingly smaller.

Also, in the present invention, the active elements and the plurality of multi-layered organic EL elements are connected to each other via a contact hole. This characteristic shortens routing distance of the wirings, thereby reducing supply timing shifts in the driving signal among the organic EL elements. This reduction makes it possible to suppress luminance unevenness of each organic EL element. Also, in order to reduce the routing area of the wirings further, it is preferable to locate the contact hole within a unit pixel. For example, the concrete structure is as follows: The contact hole which is connected to the second-layer or thereafter organic EL elements is provided on the side-surface side of the first-layer organic EL elements which correspond to the first layer when counted from the insulating-substrate side.

Also, in the present invention, in the case of employing the so-called bottom-emission structure, a reflection plate is provided on the outer side of the layer of each organic EL element which is the most distant from the insulating substrate. Meanwhile, in the case of employing the so-called top-emission structure, the reflection plate is provided on the inner side of the layer of each organic EL element which is the most proximate to the insulating substrate. Also, the plurality of light-emitting layers which exist in the same layer are configured with light-emitting layers which exist in a manner of extending all over the entire surfaces. This configuration makes it unnecessary to employ the conventional complicated manufacturing processes for the area-division for each color, thereby making it possible to simplify the manufacturing processes.

Also, as a method for driving the organic EL display apparatus including this type of pixel structure, the R, G, and B three-layer organic EL elements multi-layered in the conventional one subpixel are driven in a subframe within one and the same frame. As a result of this driving method, the display by the amount of one color main pixel (i.e., the so-called main pixel) can be implemented in a size of the conventional one color unit pixel (e.g., one color subpixel, i.e., the so-called subpixel). This characteristic allows implementation of the high-definition display.

Also, in basically the same way as the conventional technologies, in the case of representing one pixel by using the three unit pixels adjacent in the surface direction, only a part of the multi-layered organic EL elements is used, then switching the layers of the multi-layered organic EL elements with a predetermined timing. This switching method makes it possible to accomplish the implementation of the long life-expectancy as the organic EL display apparatus.

The above-described organic EL elements are configured as follows: Namely, organic EL elements for emitting one and the same color are multi-layered. Moreover, current values flowing through these organic EL elements are controlled independently of each other. On account of this configuration, by switching layers of the organic EL elements caused to emit the light, or by selecting a plurality of organic EL elements to divide current values caused to flow through the plurality of organic EL elements, it becomes possible to decrease the total electric-current value flowing through the individual organic EL elements. Accordingly, it becomes possible to implement the long life-expectancy of the organic EL display apparatus.

Also, as control schemes for controlling the above-described switching timing of the multi-layered organic EL elements, hand-operation schemes and automatic schemes are conceivable. In the case of the automatic schemes, the following methods exist: A method of detecting display state, such as estimating a luminance lowering from time-lapse change in the current flowing through the organic EL elements, and making the switching in response to the display state, a method of making the switching by counting a constant number of days, or making the switching in the frame unit. Concretely, a light-emission luminance sensor for the organic EL elements is provided, thereby detecting that the luminance of one layer of the organic EL elements has become lower than a predetermined constant value. Otherwise, a current sensor is provided, thereby detecting that the current value of one layer continues to rise up in a value larger than a constant value. Then, a control of switching the layers of the multi-layered organic EL elements caused to light up is performed based on these detections. This control makes it possible to prolong the life-expectancy of the entire organic EL display apparatus.

As the unit for an area to be switched, the line unit pixel unit, and subpixel unit exist in addition to the frame unit.

Also, as a mode in which the present invention is applied, the following mode exists: Namely, on a bottom-emission organic EL display apparatus configured on an insulating substrate, a top-emission organic EL display apparatus is directly multi-layered with no switching elements intervened therebetween. This direct multi-layering makes the insulating substrate common to both display apparatuses, thereby constructing a thin-type and light-weighted double-side organic EL display apparatus.

Also, a reflection electrode configuring the upper-layer electrode of the bottom-emission organic EL display apparatus and a reflection electrode configuring the lower-layer electrode of the top-emission organic EL display apparatus are put into co-use. This co-use makes it possible to accomplish even-thinner type implementation and even-lighter weight implementation of the double-side organic EL display apparatus.

As another mode of the present invention, the following mode exists: Namely, the first organic EL element has a configuration formed by multi-layering a first transparent electrode, a first organic light-emitting layer, and a first reflection electrode sequentially from the most proximate side to the insulating substrate. The second organic EL element has a configuration formed by multi-layering a second reflection electrode, a second organic light-emitting layer, and a second transparent electrode sequentially from the most proximate side to the insulating substrate. Moreover, the active elements for driving the first organic EL element and the second organic EL element are provided between the insulating substrate and the first organic EL element.

Moreover, as a mode for embodying the present invention concretely, the following mode exists: Namely, the second transparent electrode of the second organic EL element and the active element for driving the second organic EL element are connected to each other via a contact hole which is located by penetrating an insulating film provided at the end portion of the first organic EL element.

Furthermore, it is preferable that the first reflection electrode of the first organic EL element and the second reflection electrode of the second organic EL element be configured using one double-side reflection electrode which plays a role of the two reflection electrodes.

Also, as another mode in which the present invention is applied, a mode exists where the following configuration components are multi-layered in the following sequence: Namely, an insulating substrate, an active element formed on the insulating substrate, a first transparent electrode connected to the active element and separated for each color subpixel, a first light-emitting layer separated for each color subpixel, a double-side reflection electrode separated for each color subpixel, a second light-emitting layer separated for each color subpixel, and a second transparent electrode separated for each color subpixel.

It is preferable that this double-side reflection electrode has an aperture portion for each color subpixel, and that the active element and the second transparent electrode be electrically connected to each other via a contact hole which passes through the aperture portion of the double-side reflection electrode.

Also, as another mode in which the present invention is applied, the following mode exists: Namely, the first organic EL element or the second organic-EL element is one of the subpixels which configure one color main pixel. Namely, the plurality of first organic EL elements or second organic EL elements which are adjacent on the insulating substrate and in a direction parallel to the surface of the insulating substrate respectively configure the one color main pixel on the upper and lower layers of the double-side reflection electrode.

Also, it is preferable that the double-side reflection electrode has the following configuration: Namely, the double-side reflection electrode is located in such a manner that the double-side reflection electrode is overlapped on the first transparent electrode configuring the first organic EL element and the second transparent electrode configuring the second organic EL element. Moreover, the double-side reflection electrode has the aperture portion for each color subpixel including the first organic EL element and the second organic EL element, the contact hole passing through the aperture portion.

Incidentally, the present invention is not limited to the above-described configuration and configurations disclosed in embodiments which will be described later. Namely, various types of modifications are executable without departing from the technical ideas of the present invention.

The respective units and methods according to the present invention allow the implementation of the long life-expectancy and high-definition performance of the active-driving organic EL display apparatus which is based on the structure where the plurality of organic EL elements are multi-layered on the insulating substrate.

Other objects, features and advantages of the invention will become apparent from the following description of the embodiments of the invention taken in conjunction with the accompanying drawings.

### BRIEF DESCRIPTION OF THE DRAWINGS

FIG. 1 is a conceptual diagram for explaining a first embodiment of the present invention;

FIG. 2 illustrates cross-sectional views acquired by cutting off the first embodiment along an A-A′ line, a B-B′ line, and a C-C′ line in FIG. 1:

FIG. 3 is a conceptual diagram for explaining a second embodiment of the present invention;

FIG. 4 illustrates cross-sectional views acquired by cutting off the second embodiment along an A-A′ line, a B-B′ line, and a C-C′ line in FIG. 3:

FIG. 5 is a conceptual diagram for explaining a third embodiment of the present invention;

FIG. 6 illustrates cross-sectional views acquired by cutting off the third embodiment along an A-A′ line, a B-B′ line, and a C-C′ line in FIG. 5:

FIGS. 7A-7P are flowchart diagrams for explaining one example of the manufacturing processes for the organic EL display apparatus explained in the first embodiment of the present invention;

FIG. 8 is an explanatory diagram for explaining an example of the equivalent circuit to the pixel of the organic EL display apparatus of the present invention.

FIG. 9 is a conceptual diagram for explaining a fourth embodiment of the present invention;

FIGS. 10 (a), (b), and (c) illustrate cross-sectional views acquired by cutting off the fourth embodiment along an A-A′ line, a B-B′ line, and a C-C′ line in FIG. 12:

FIG. 11 is an explanatory diagram for explaining an example of the equivalent circuit to the pixel of the organic EL display apparatus of the present invention;

FIG. 12 is a diagram for explaining one of switching modes for the multi-layered each-color organic EL element units;

FIG. 13 is a diagram for explaining a configuration example of the system whose long life-expectancy is implemented by switching the multi-layered units;

FIG. 14A to FIG. 14P are flowchart diagrams for explaining one example of the manufacturing processes for the organic EL display apparatus explained in the fourth embodiment of the present invention;

FIG. 15 is a conceptual diagram for explaining a fifth embodiment of the organic EL display apparatus of the present invention;

FIGS. 16 (a) and (b) illustrate cross-sectional views acquired by cutting off the fifth embodiment along an A-A′ line and a B-B′ line in FIG. 18:

FIG. 17 is an explanatory diagram for explaining an example of the equivalent circuit to the pixel of the organic EL display apparatus of the present invention; and

FIG. 18A to FIG. 18J are flowchart diagrams for explaining one example of the manufacturing processes for the double-side organic EL display apparatus explained in the fifth embodiment of the present invention.

### DESCRIPTION OF THE INVENTION

Hereinafter, referring to the drawings of embodiments, the explanation will be given below concerning the embodiments of the present invention.

### Embodiment 1

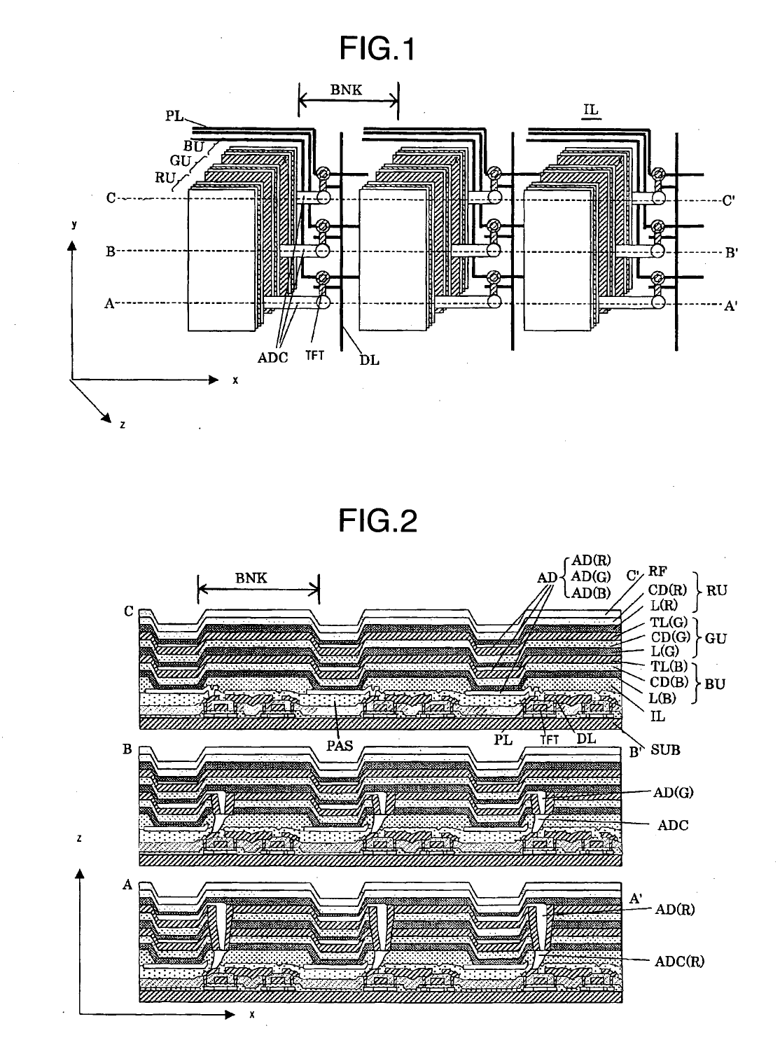

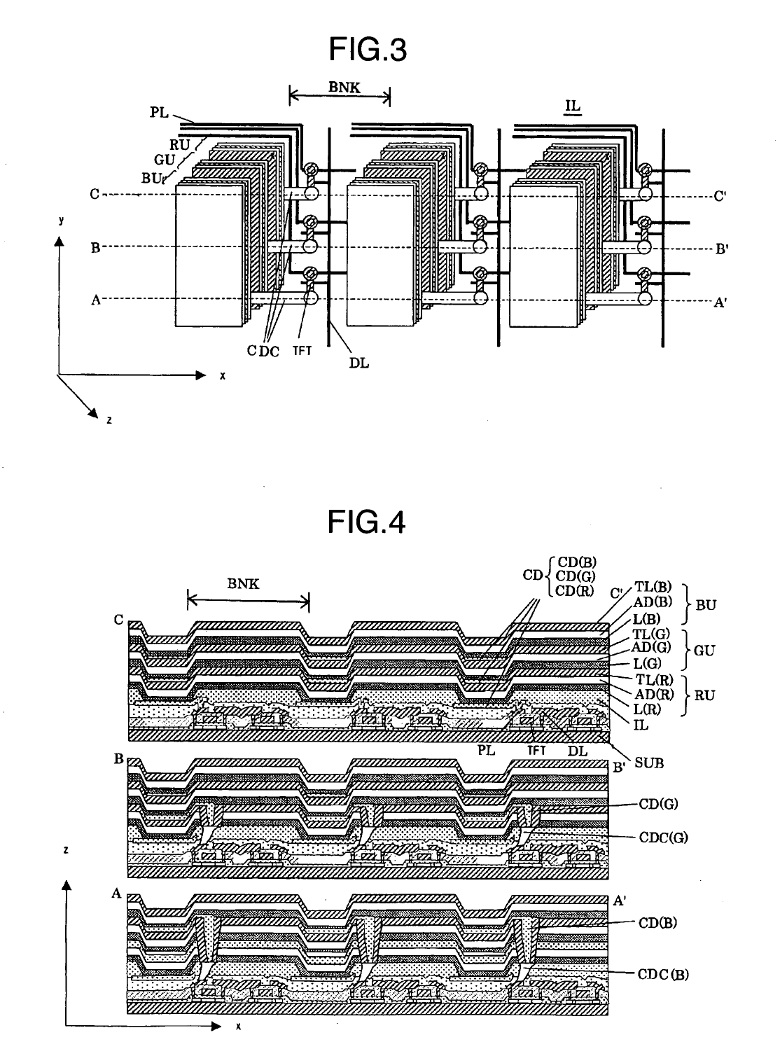

FIG. 1 is a conceptual diagram for explaining a first embodiment of the present invention. Also, FIG. 2 illustrates cross-sectional views acquired by cutting off the first embodiment along an A-A′ line, a B-B′ line, and a C-C′ line in FIG. 1. The first embodiment is the so-called bottom-emission pixel display apparatus for emitting out display light from an insulating-substrate SUB side. Each of the primary colors, i.e., red (R), green (G), and blue (B), corresponds to a unit pixel (i.e., a subpixel). These three color unit pixels form one color main pixel. In FIG. 1, the insulating substrate (hereinafter, glass substrate) SUB illustrated in FIG. 2 exists in the back of the paper surface. An active pixel circuit where thin-film transistors are used as the active elements is fabricated into the main surface (i.e., inner surface) of this glass substrate SUB. An inter-layer insulating film IL is formed in the upper layer of this active pixel circuit.

On the inter-layer insulating film IL, the blue (B) organic EL element BU, the green (G) organic EL element GU, and the red (R) organic EL element RU are multi-layered in this order. Namely, it turns out that the three unit pixels are located within the area of one unit pixel. This location makes it possible to accomplish implementation of the higher-definition performance as compared with the conventional location where the respective organic EL elements are located in the substrate-surface direction.

FIG. 1 and FIG. 2 illustrate full-color three pixels. A bank referred to as “bank” is provided between the respective pixels. This bank BNK is utilized for the area limitation in a formation process of forming organic films of each organic EL element, especially in a formation process of forming the light-emitting layers. The area of this bank is not utilized for the display. The thin-film transistors TFTs or the like which configure the above-described active pixel circuit are formed in the portion hidden by this bank BNK.

The thin-film transistors TFTs are connected to a signal wiring DL, a power-supply wiring PL, and a scanning wiring (not illustrated). One thin-film transistor TFT is illustrated for each organic EL element in FIG. 1, and two thin-film transistors TFTs are illustrated for each organic EL element in FIG. 2. The details, however, will be explained later. Incidentally, the anode of each organic EL element is connected to each thin-film transistor TFT via an anode contact ADC.

In FIG. 2, excluding a reflection electrode RF in the uppermost layer, the blue (B) organic EL element BU, the green (G) organic EL element GU, and the red (R) organic EL element RU, which are multi-layered on the inter-layer insulating film IL, are of the same layer structure. Namely, directly above a blue-used anode AD (B) in a pixel portion (i.e., pixel aperture) formed by removing a part of the inter-layer insulating film IL, the blue (B) organic EL element BU is formed. Here, the blue (B) organic EL element BU includes a blue-used light-emitting layer L (B) including an organic film, a blue-used cathode CD (B) including a transparent electrode, and a transparent insulating film TL (B).

On this blue (B) organic EL element BU, the green (G) organic EL element GU is formed. Here, the green (G) organic EL element GU includes a green-used anode AD (G), a green-used light-emitting layer L (G) including an organic film, a green-used cathode CD (G) including a transparent electrode, and a transparent insulating film TL (G). Moreover, on this green (G) organic EL element GU, the red (R) organic EL element RU is formed. Here, the red (R) organic EL element RU includes a red-used anode AD (R), a red-used light-emitting layer L (R) including an organic film, a red-used cathode CD (R) including a transparent electrode, and a transparent insulating film TL (R). Furthermore, in the uppermost layer, the reflection electrode RF is formed as the film.

The anodes AD (B), AD (G), and AD (R) of the respective organic EL elements BU, GU, and RU are each connected to its own thin-film transistor TFT in the following manner: Namely, as illustrated in the C-C′ cross section in FIG. 2, the blue-used anode AD (B), which is the most proximate to the glass substrate, is electrically connected to an output electrode of the thin-film transistor TFT via a contact hole which is bored in a protection film (i.e., passivation film) PAS of the thin-film transistor formation layer.

Similarly, as illustrated in the B-B′ cross section in FIG. 2, the green-used anode AD (G) is electrically connected to an output electrode of the thin-film transistor TFT via the contact hole which is bored in the passivation film PAS, the inter-layer insulating film IL, the blue-used light-emitting layer L (B), and the transparent insulating film TL (B). Moreover, as illustrated in the A-A′ cross section in FIG. 2, the red-used anode AD (R) is electrically connected to an output electrode of the thin-film transistor TFT via the contact hole which is bored in the passivation film PAS, the inter-layer insulating film IL, the blue-used light-emitting layer L (B), the transparent insulating film TL (B), the green-used light-emitting layer L (G), the green-used cathode CD (G), and the transparent insulating film TL (G).

In the above-described configuration of the first embodiment, on the glass substrate on which the thin-film transistors TFTs are formed, 70-nm MTDATA (4,4′4″-tris[-N-(-3-methylphenyl)-N-phenylamino]triphenylamine), 10-nm α-NPD, a 60-nm (5%) co-evaporation film of tris (8-hydroxyquinoline) aluminum (Alq)/anthracene, and 60-nm Alq are evaporated as the organic EL light-emitting layer. Moreover, on the organic EL light-emitting layer, 0.8-nm Mg and 70-nm ITO films are formed as transparent cathode material. After that, a 50-nm SiN film is formed, then forming 70-nm ITO, 70-nm MTDATA, 10-nm α-NPD, 60-nm Alq, 0.8-nm Mg, and 70-nm ITO films. Furthermore, a 50-nm SiN film is formed, then forming 70-nm ITO, 70-nm MTDATA, 10-nm αc-NPD, 60-nm (2%) Alq/DCJT, 0.5-nm LiF, and 100-nm aluminum films.

Applying a 6-V direct voltage to the organic EL display apparatus manufactured in this way has successfully resulted in acquisition of an 800-cd/m2 white light-emission. Also, changing applied voltages to the respective organic EL elements BU, GU, and RU has allowed implementation of the tone-level representation. Also, in this organic EL display apparatus, the half-life time-period for 100-cd/m2 luminance at room temperature has been found to be 10000 hours or more.

Also, in the above-described configuration of the first embodiment, on the glass substrate on which the thin-film transistors TFTs are formed, 70-nm MTDATA, 10-nm α-NPD, a 60-nm (5%) co-evaporation film of tris (8-hydroxyquinoline) aluminum (Alq)/anthracene, and 60-nm Alq are evaporated as the organic EL light-emitting layer. Moreover, on the organic EL light-emitting layer, 0.8-nm V2O5 and 70-nm ITO films are formed as the transparent cathode material. After that, a 50-nm SiN film is formed, then forming 70-nm ITO, 70-nm MTDATA, 10-nm α-NPD, 60-nm Alq, 0.8-nm V2O5, and 70-nm ITO films. Furthermore, a 50-nm SiN film is formed, then forming 70-nm ITO, 70-nm MTDATA, 10-nm α-NPD, 60-nm (2%) Alq/DCJT, 60-nm Alq, 0.5-nm LiF, and 100-nm aluminum films.

Applying the 6-V direct voltage to the organic EL display apparatus manufactured in this way has successfully resulted in acquisition of a 1000-cd/m2 white light-emission. Also, changing the applied voltages to the respective organic EL elements BU, GU, and RU has allowed implementation of the tone-level representation. Also, in this organic EL display apparatus, the half-life time-period for the 100-cd/m2 luminance at room temperature has been found to be 10000 hours or more.

Moreover, in the above-described configuration of the first embodiment, on the glass substrate on which the thin-film transistors TFTs are formed, 70-nm MTDATA, 10-nm α-NPD, 60-nm (5%) Alq/anthracene, and 60-nm Alq are evaporated as the organic EL light-emitting layer. Moreover, on the organic EL light-emitting layer, 0.8-nm V2O5 and 70-nm ITO films are formed as the transparent cathode material. After that, a 50-nm SiN film is formed, then forming 70-nm ITO, 70-nm MTDATA, 10-nm α-NPD, 60-nm (5%) Alq/Ir (ppy), 0.8-nm V205, and 70-nm ITO films. Furthermore, a 50-nm SiN film is formed, then forming 70-nm ITO, 70-nm MTDATA, 10-nm α-NPD, 60-nm (2%) Alq/DCM2/Ir (ppy), 60-nm Alq, 0.5-nm LiF, and 100-nm aluminum films.

Applying the 6-V direct voltage to the organic EL display apparatus manufactured in this way has successfully resulted in acquisition of a 2000-cd/m2 white light-emission. Also, changing the applied voltages to the respective organic EL elements BU, GU, and RU has allowed implementation of the tone-level representation. Also, in this organic EL display apparatus, the half-life time-period for the 100-cd/m2 luminance at room temperature has been found to be 15000 hours or more.

### Embodiment 2

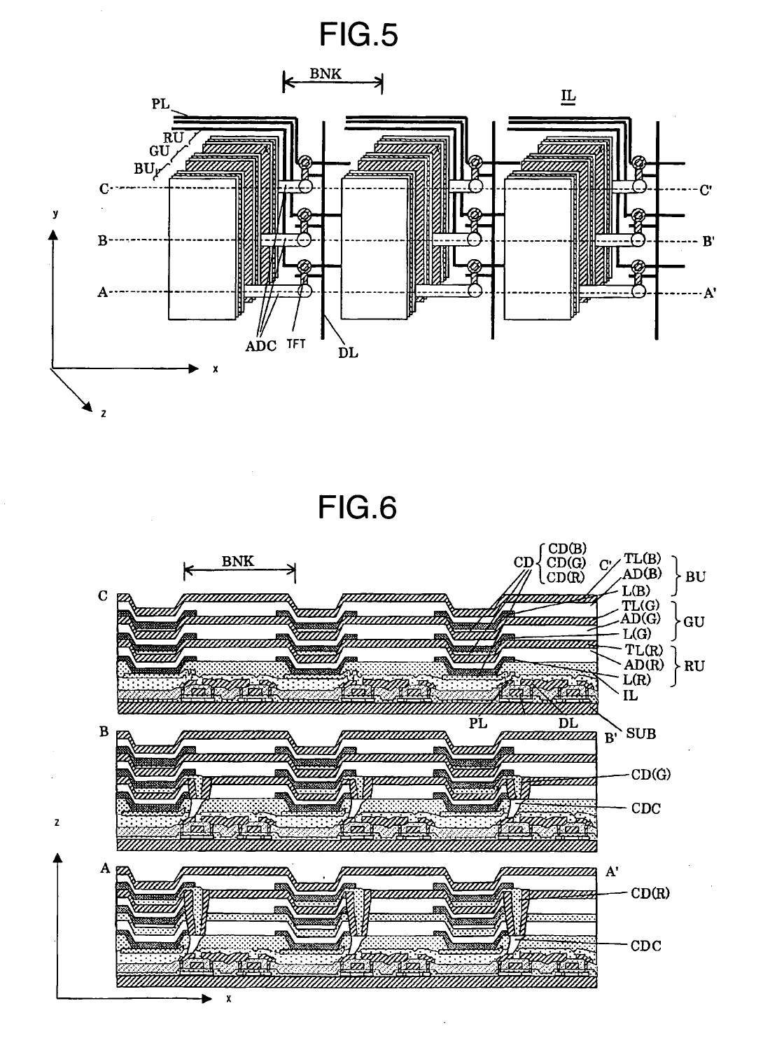

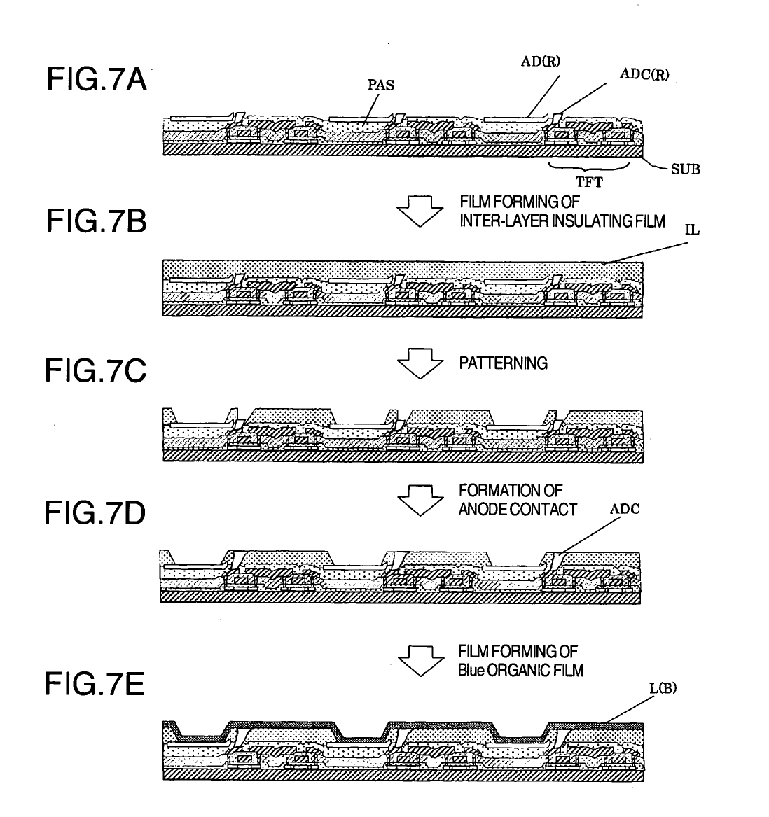

FIG. 3 is a conceptual diagram for explaining a second embodiment of the present invention. Also, FIG. 4 illustrates cross-sectional views acquired by cutting off the second embodiment along an A-A′ line, a B-B′ line, and a C-C′ line in FIG. 3. The second embodiment is the so-called top-emission pixel display apparatus for emitting out display light from the opposite side to the insulating substrate SUB. In this organic EL display apparatus, the red (R) organic EL element RU, the green (G) organic EL element GU, and the blue (B) organic EL element BU are multi-layered in this order from the glass-substrate SUB side. Similarly to the first embodiment, the three unit pixels are located within the area of one unit pixel. This location makes it possible to accomplish implementation of the higher-definition performance as compared with the conventional location where the respective organic EL elements are located in the substrate-surface direction.

In FIG. 4, the red (R) organic EL element RU, the green (G) organic EL element GU, and the blue (B) organic EL element BU, which are multi-layered on the inter-layer insulating film IL, are of the same layer structure. Namely, directly above a red-used anode AD (R) in a pixel portion (i.e., pixel aperture) formed by removing a part of the inter-layer insulating film IL, the red (R) organic EL element RU is formed. Here, the red (R) organic EL element RU includes a red-used light-emitting layer L (R) including an organic film, a red-used cathode CD (R) including a transparent electrode, and a transparent insulating film TL (R).

On this red (R) organic EL element RU, the green (G) organic EL element GU is formed. Here, the green (G) organic EL element GU includes a green-used anode AD (G), a green-used light-emitting layer L (G) including an organic film, a green-used cathode CD (G) including a transparent electrode, and a transparent insulating film TL (G). Moreover, on this green (G) organic EL element GU, the blue (B) organic EL element BU is formed. Here, the blue (B) organic EL element BU includes a blue-used anode AD (B), a blue-used light-emitting layer L (B) including an organic film, a blue-used cathode CD (B) including a transparent electrode, and a transparent insulating film TL (B). In the second embodiment, there is provided none of the reflection film indicated in the first embodiment.

The anodes AD (R), AD (G), and AD (B) of the respective organic EL elements RU, GU, and BU are each connected to its own thin-film transistor TFT in the following manner: Namely, as illustrated in the C-C′ cross section in FIG. 4, the red-used anode AD (R), which is the most proximate to the glass substrate, is electrically connected to an output electrode of the thin-film transistor TFT via a contact hole which is bored in a protection film (i.e., passivation film) PAS of the thin-film transistor formation layer.

Similarly, as illustrated in the B-B′ cross section in FIG. 4, the green-used anode AD (G) is electrically connected to an output electrode of the thin-film transistor TFT via the contact hole which is bored in the passivation film PAS, the inter-layer insulating film IL, the red-used light-emitting layer L (R), and the transparent insulating film TL (R). Moreover, as illustrated in the A-A′ cross section in FIG. 4, the blue-used anode AD (B) is electrically connected to an output electrode of the thin-film transistor TFT via the contact hole which is bored in the passivation film PAS, the inter-layer insulating film IL, the red-used light-emitting layer L (R), the transparent insulating film TL (R), the green-used light-emitting layer L (G), the green-used cathode CD (G), and the transparent insulating film TL (G). The other configurations are the same as those in the first embodiment.

In the configuration of the second embodiment, basically the same materials are used as those in the first embodiment. Moreover, the configuration is embodied in basically the same film thicknesses, then being driven under basically the same driving conditions as those in the first embodiment. This driving has resulted in acquisition of basically the same effects.

### Embodiment 3

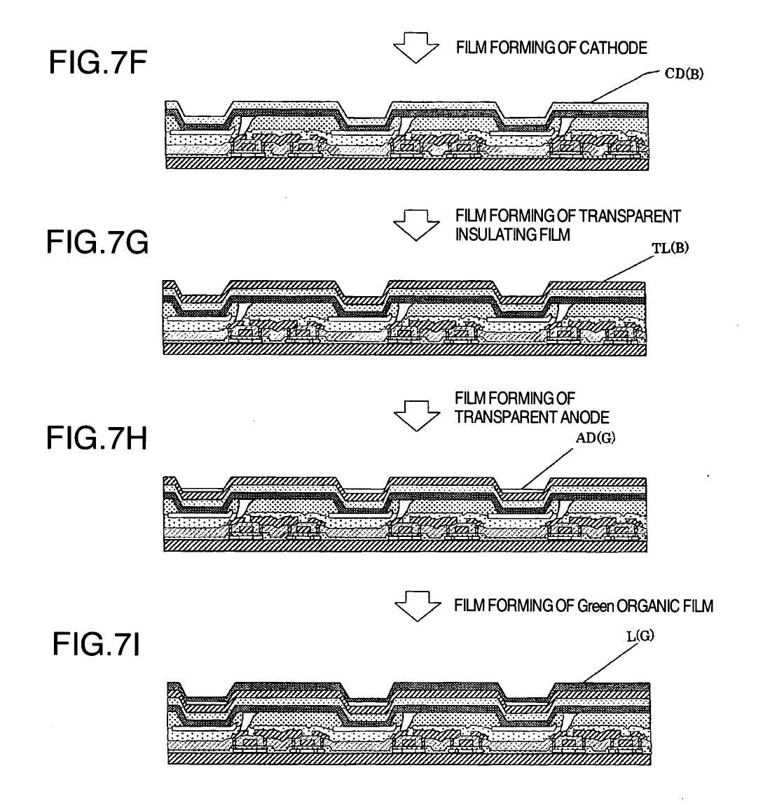

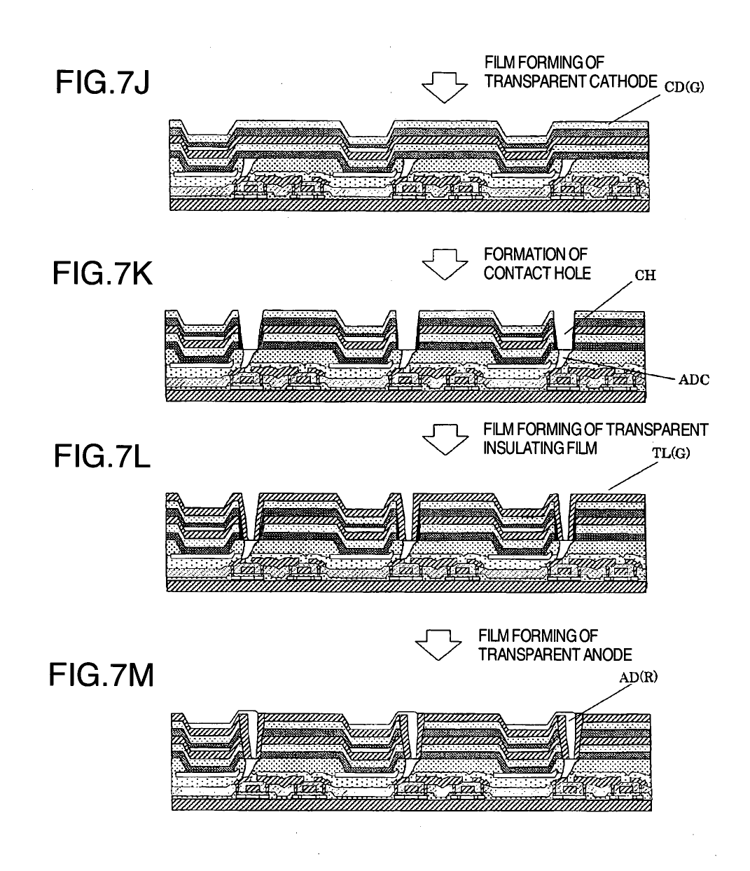

FIG. 5 is a conceptual diagram for explaining a third embodiment of the present invention. Also, FIG. 6 illustrates cross-sectional views acquired by cutting off the third embodiment along an A-A′ line, a B-B′ line, and a C-C′ line in FIG. 5. The third embodiment is basically the same as the second embodiment except a point that the organic light-emitting layers L (R), L (G), and L (B) in the second embodiment are formed by evaporation using a mask. Namely, the organic light-emitting layers L (R), L (G), and L (B) configuring the red, green, and blue organic EL elements RU, GU, and BU with the three-layer structure are evaporated using the mask in only the aperture portion of the pixel (i.e., between the banks BNKs). The other configurations are the same as those in the second embodiment.

In the configuration of the third embodiment, basically the same materials are used as those in the second embodiment. Moreover, the configuration is embodied in basically the same film thicknesses, then being driven under basically the same driving conditions as those in the second embodiment. This driving has resulted in acquisition of basically the same effects.

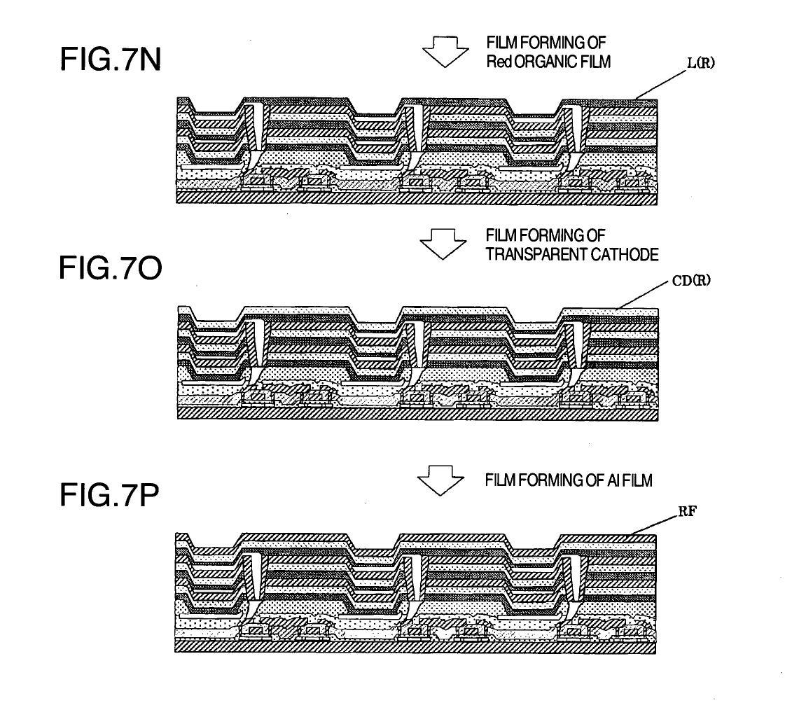

Next, referring to FIGS. 7A to 7P, the explanation will be given below concerning one example of the manufacturing processes for the organic EL display apparatus explained in the first embodiment of the present invention. These manufacturing processes will be executed in the order indicated by all the through FIGS. 7A to 7P. Incidentally, FIGS. 7A to 7P correspond to the cross-sectional view acquired by cutting off the first embodiment along the A-A′ line in FIG. 1. The drawing in FIG. 7A illustrates the rear-surface substrate illustrated in FIG. 2. On this rear-surface substrate, the thin-film transistors TFTs are formed on the glass substrate SUB, and patterning for the red-used transparent anode AD (R) is performed on the protection film PAS. The inter-layer insulating film IL is formed on this rear-surface substrate (FIG. 7B). Then, the transparent-anode portion (i.e., the aperture portion of the subpixel) is removed using a photolithography method, and simultaneously the contact hole is bored (FIG. 7C).

The organic layer is removed using a laser milling method, thereby providing an electrically-conductive member, which is preferably ITO, in such a manner that the electrically-conductive member is buried within the contact hole (FIG. 7D). This anode contact becomes the electrode for connecting the respective thin-film transistors TFTs to the anodes of the second and third organic EL elements which will be formed on the upper layers. Next, the blue-used organic film L (B) which becomes the blue (B) organic EL film is formed (FIG. 7E). This blue-used organic film L (B) is obtained by evaporating a blue-used hole injection inter-layer insulating film, a hole transportation layer, a light-emitting layer, and an electron transportation layer in this order. In FIG. 7F, the transparent cathode CD (B) is formed on the organic film L (B). After that, the transparent insulating film TL (B) is formed (FIG. 7G). Next, patterning for the green-used transparent anode AD (G) is performed (FIG. 7H). At this time, the green-used transparent anode AD (G) is connected to a not-illustrated output electrode of the green-used thin-film transistor. Moreover, the green-used organic film L (G) is formed in accordance with basically the same processing steps as those in the above-described blue-used organic film L (B) (FIG. 7I).

The green-used transparent cathode CD (G) is formed on the green-used organic film L (G) (FIG. 7J). After that, a contact hole CH, which attains from this cathode CD (G) to the anode contact ADC in the depth direction, is formed using the laser milling method (FIG. 7K). The transparent insulating film TL (G) is formed including the inner wall of this contact hole CH (FIG. 7L). Next, patterning for the red-used transparent anode AD (R), which attains to the anode contact ADC via the contact hole CH, is performed (FIG. 7M).

The red-used organic film L (R) is formed in such a manner that the film L (R) covers this red-used transparent anode AD (R) (FIG. 7N). Similarly to the above-described respective blue-used and green-used organic films, this red-used organic film L (R) is also formed by being multi-layered. The red-used transparent cathode CD (R) is formed on the upper layer of the red-used organic film L (R) (FIG. 70). Finally, the reflection electrode RF is formed (FIG. 7P). This reflection electrode RF is formed by evaporation of aluminum. Incidentally, as the cathode CD (R), a reflection film on which aluminum is evaporated may be co-used.

The execution of a series of manufacturing processes like this allows acquisition of the above-described organic EL display apparatus in the first embodiment. Incidentally, the explanation about manufacturing processes for the pixel display apparatuses in the second embodiment and the third embodiment is basically the same as the above-described explanation given in FIG. 7 to FIG. 10. Only the difference existing therebetween is the formation order of the red, green, and blue organic EL elements.

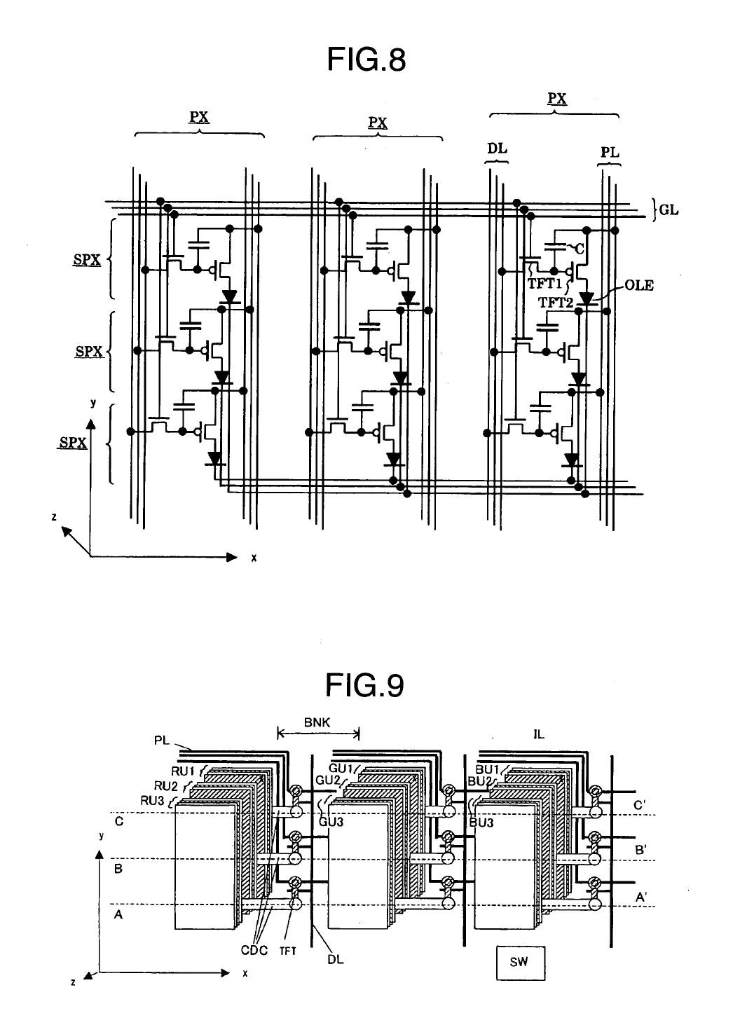

FIG. 8 is an explanatory diagram for explaining an example of the equivalent circuit to the pixel of the organic EL display apparatus of the present invention. In FIG. 8, a notation PX denotes one color main pixel. Each color main pixel PX includes three color subpixels SPXs which are arranged in the up-and-down direction in the drawing. Moreover, each subpixel SPX includes a first thin-film transistor TFT 1 (i.e., switching transistor), a second thin-film transistor TFT 2 (i.e., signal-latching transistor), a latching capacitor C, and an organic EL light-emitting unit OLE. These configuration components are connected to three scanning-signal wirings GL corresponding to each color, the same three data-signal wirings DL corresponding thereto, and the same three power-supply wirings PL corresponding thereto. Incidentally, in FIG. 1, FIG. 3, and FIG. 5, only the second thin-film transistor TFT 2 in FIG. 8 has been illustrated as the TFT. Also, the configuration illustrated in FIG. 8 is the basic circuit configuration. Accordingly, as the driving circuit for the organic EL display apparatus of the present invention, various types of configurations exist other than this basic configuration.

### Embodiment 4

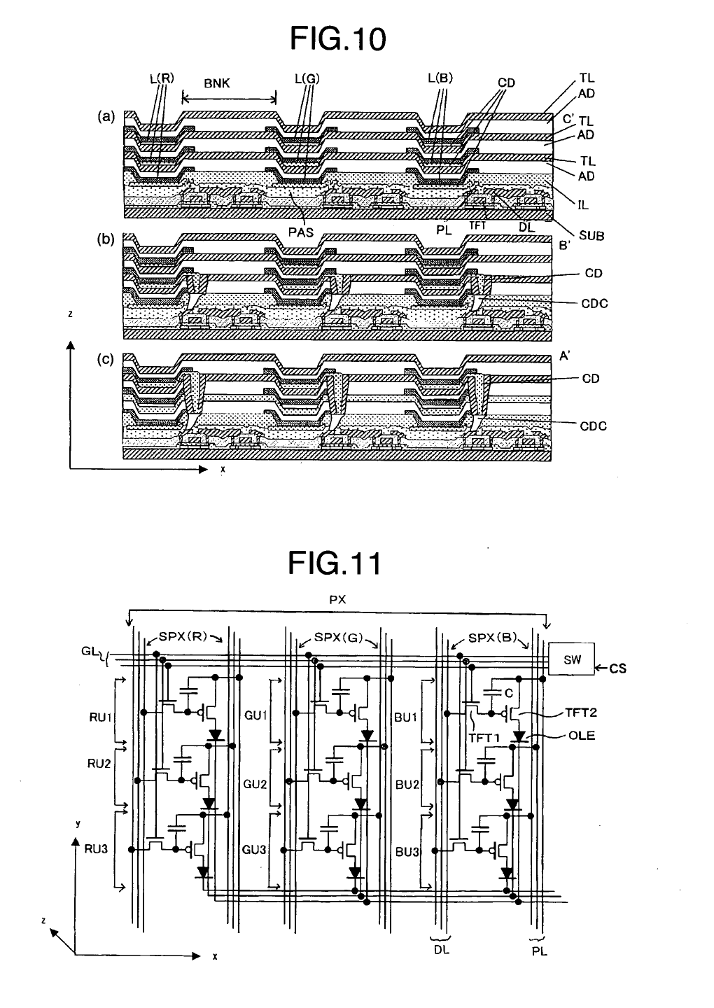

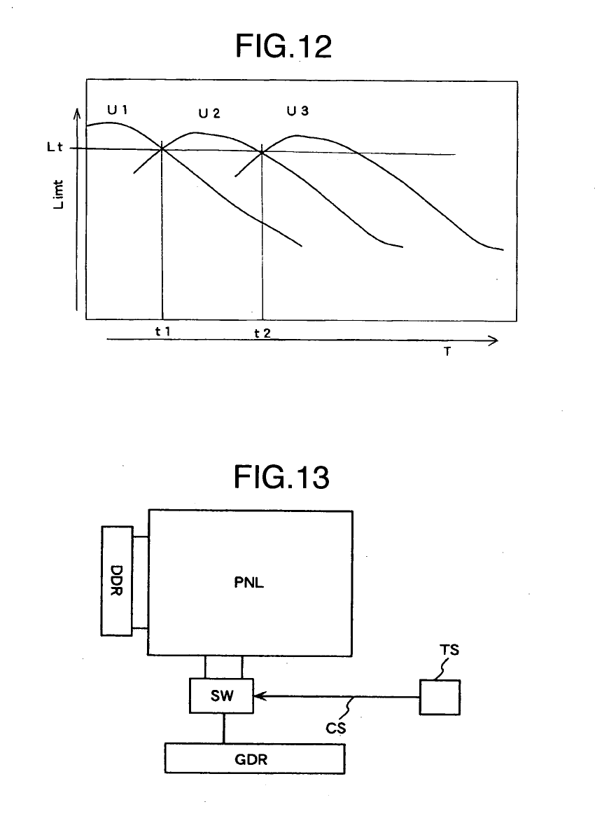

FIG. 9 is a conceptual diagram for explaining a fourth embodiment of the present invention. Also, FIGS. 10 (a), (b), and (c) illustrate cross-sectional views acquired by cutting off the fourth embodiment along an A-A′ line, a B-B′ line, and a C-C′ line in FIG. 9. The fourth embodiment is the so-called top-emission pixel display apparatus for emitting out display light from the opposite side to an insulating substrate SUB. In this organic EL display apparatus, three-layer-structured red (R) organic EL element units RU1, RU2, and RU3, three-layer-structured green (G) organic EL element units GU1, GU2, and GU3, and three-layer-structured blue (B) organic EL element units BU1, BU2, and BU3 are multi-layered on an inter-layer insulating film IL formed on the main surface of the glass substrate SUB. Namely, the three-layer-structured each-color organic EL element units are formed within the area of one color subpixel. These three each-color subpixels configure one color main pixel.

In FIG. 9, the insulating substrate (hereinafter, also referred to as the glass substrate) SUB illustrated in FIGS. 10 (a), (b), and (c) exists in the back of the paper surface. An active pixel circuit where thin-film transistors are used as the active elements is fabricated into the main surface (i.e., inner surface) of this glass substrate SUB. The inter-layer insulating film IL is formed in the upper layer of this active pixel circuit.

On the inter-layer insulating film IL, the three-layer-structured red (R) organic EL element units RU1, RU2, and RU3, the three-layer-structured green (G) organic EL element units GU1, GU2, and GU3, and the three-layer-structured blue (B) organic EL element units BU1, BU2, and BU3 are located within a surface parallel to the substrate surface. Namely, it turns out that the three-layer-structured each-color organic EL element units are located within the area of one color unit pixel (i.e., subpixel). Furthermore, in the present embodiment, there is provided a multi-layered-units switching circuit SW for switching the three-layer-structured each-color organic EL element units.

FIG. 9 and FIGS. 10 (a), (b), and (c) illustrate the three each-color subpixels which configure one full-color main pixel. A bank referred to as “bank” is provided between the respective subpixels. This bank BNK is utilized for the area limitation in a formation process of forming organic films of each organic EL element, especially in a formation process of forming the light-emitting layers. The area of this bank is not utilized for the display. The thin-film transistors TFTs or the like which configure the above-described active pixel circuit are formed in the portion hidden by this bank BNK.

The thin-film transistors TFTs are connected to a signal wiring DL, a power-supply wiring PL, and a scanning wiring (not illustrated). One thin-film transistor TFT is illustrated for each organic EL element in FIG. 9, and two thin-film transistors TFTs are illustrated for each organic EL element in FIGS. 10 (a), (b), and (c). The details, however, will be explained later. Incidentally, the anode of each organic EL element is connected to each thin-film transistor TFT via an anode contact ADC.

In FIGS. 10 (a), (b), and (c), the three-layer-structured red (R) organic EL element units RU1, RU2, and RU3, the three-layer-structured green (G) organic EL element units GU1, GU2, and GU3, and the three-layer-structured blue (B) organic EL element units BU1, BU2, and BU3, which are multi-layered on the inter-layer insulating film IL, are of the same layer structure. Namely, directly above a cathode CD formed by removing a part of the inter-layer insulating film IL in a pixel portion of each-color subpixels, the first-layer organic EL element units RU1, GU1, and BU1 illustrated in FIG. 9 are formed. Here, the first-layer organic EL element units RU1, GU1, and BU1 includes first-layer light-emitting layers L (R), L (G), and L (B) including an organic film, a first-layer anode AD, and a first-layer insulating film TL. In FIGS. 10 (a), (b), and (c), notations for the units are omitted in order to avoid complexity. Hereinafter, the notations will be omitted similarly.

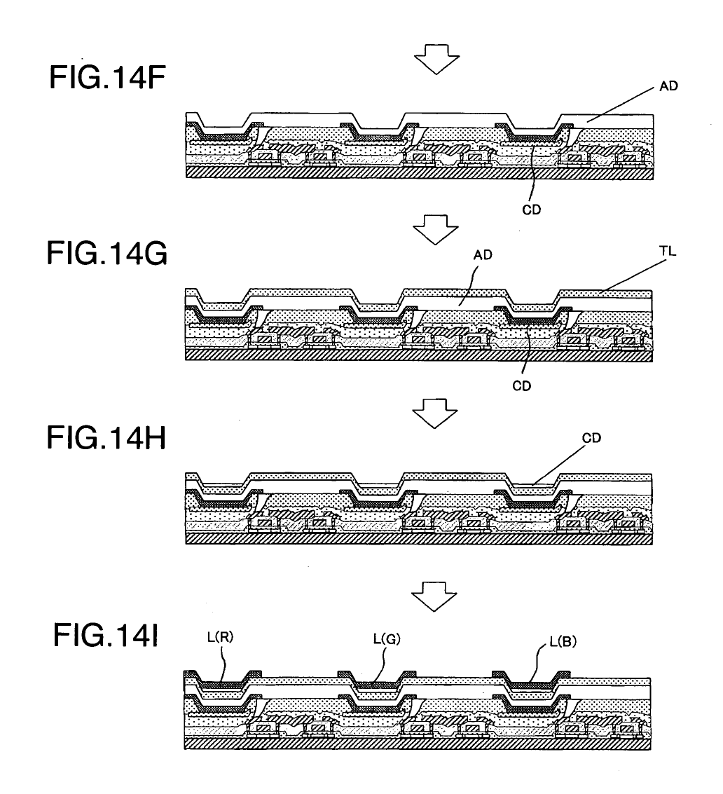

On this first-layer organic EL element units RU1, GU1, and BU1, the second-layer organic EL element units RU2, GU2, and BU2 illustrated in FIG. 12 are formed. Here, the second-layer organic EL element units RU2, GU2, and BU2 includes a second-layer cathode CD, second-layer light-emitting layers L (R), L (G), and L (B) including an organic film, a second-layer anode AD, and a second-layer insulating film TL.

In addition, on this second-layer organic EL element units RU2, GU2, and BU2, the third-layer organic EL element units RU3, GU3, and BU3 illustrated in FIG. 9 are formed. Here, the third-layer organic EL element units RU3, GU3, and BU3 includes a third-layer cathode CD, third-layer light-emitting layers L (R), L(G), and L(B) including an organic film, a third-layer anode AD, and a third-layer insulating film TL.

The cathodes CD of the respective organic EL element units RU2, GU2, and BU2 illustrated in FIG. 9 are each connected to its own thin-film transistor TFT in the following manner: Namely, as illustrated in the C-C′ cross section in FIG. 10 (a), the first-layer cathode CD, which is the most proximate to the insulating substrate SUB, is electrically connected to an output electrode of the thin-film transistor TFT via a contact hole which is bored in a protection film (i.e., passivation film) PAS of the thin-film transistor formation layer.

Similarly, as illustrated in the B-B′ cross section in FIG. 10 (b), the second-layer cathode CD is electrically connected to an output electrode of the thin-film transistor TFT via the contact hole which is bored in the passivation film PAS, the inter-layer insulating film IL, the first-layer light-emitting layers, and the first-layer insulating film TL. Furthermore, as illustrated in the A-A′ cross section in FIG. 10 (c), the third-layer cathode CD is electrically connected to an output electrode of the thin-film transistor TFT via the contact hole which is bored in the passivation film PAS, the inter-layer insulating film IL, the second-layer light-emitting layers, the second-layer insulating film TL, the first-layer light-emitting layers, the first-layer anode AD, and the first-layer insulating film TL.

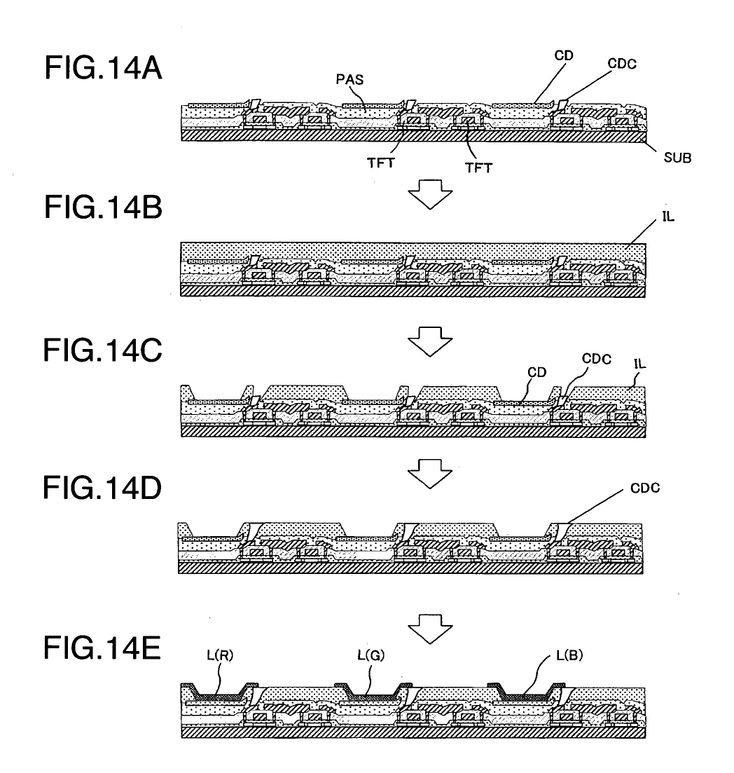

FIG. 11 is an explanatory diagram for explaining an example of the equivalent circuit to the pixel of the organic EL display apparatus of the present invention. In FIG. 11, a notation PX denotes one color main pixel. Each color main pixel PX includes three color subpixels SPX(R), SPX(G), and SPX(B) which are arranged in the right-to-left direction in FIG. 11. The red subpixel SPX(R) includes the units RU1, RU2, and RU3 which are multi-layered in the direction (i.e., z direction) perpendicular to the paper surface in FIG. 11. Similarly, the green subpixel SPX(G) includes the units GU1, GU2, and GU3 which are multi-layered in the z direction. The blue subpixel SPX(B) includes the units BU1, BU2, and BU3 which are multi-layered in the z direction.

Each-color unit is represented by an equivalent circuit including two thin-film transistors TFT 1 and TFT 2, a capacitor C, and an organic EL light-emitting unit OLE. Also, in FIG. 11, three wirings GL extending in the right-to-left direction (i.e., x direction) in FIG. 11 are scanning-signal lines (gate lines). Three wirings DL extending in the up-and-down direction are display-signal lines (data lines). Three wirings PL similarly extending in the up-and-down direction are power-supply lines (current-supply lines). Each of these lines is provided for each unit which configures each-color subpixel.

Incidentally, in FIG. 9, only the second thin-film transistor TFT 2 in FIG. 11 has been illustrated as the TFT. Also, the configuration illustrated in FIG. 11 is the basic circuit configuration. Accordingly, as the driving circuit for the organic EL display apparatus of the present invention, various types of configurations exist other than this basic configuration.

Also, in the fourth embodiment, the multi-layered-units switching circuit SW, i.e., the switch for switching the three-layer-structured each-color organic EL element units, is provided on the gate lines GL. The switching circuit SW is configured to select and light up one of the three-layer-structured each-color organic EL element units. The data lines DL and the current-supply lines PL are connected in common at the supply points, thereby making it possible to simplify the circuit configuration of the multi-layered units. Incidentally, switching the multi-layered units may also be performed using the data lines DL and the current-supply lines PL. Otherwise, the switching can also be performed by combining the gate lines GL, the data lines DL, and the current-supply lines PL.

FIG. 12 is a diagram for explaining one of switching modes for the multi-layered each-color organic EL element units. The organic EL element units lower in their light-emission efficiencies with a lapse of the driving time T. The lowering in the light-emission efficiencies can be detected by detecting the light-emission intensities using a luminance sensor or increases in the current values. Either or both of these detection signals is or are transmitted to a switching-control-signal generation circuit, thereby controlling the multi-layered-units switching circuit SW.

In FIG. 12, the luminance at the switching point-in-time is set at Lt in advance. Then, for example, at a point-in-time t1 when the light-emission luminance of the first-layer organic EL element unit has attained to Lt, the first-layer unit is switched to the second-layer organic EL element unit. Moreover, at a point-in-time t2 when the light-emission luminance of the second-layer unit has attained to Lt, the second-layer unit is switched to the third-layer organic EL element unit. On account of this switching, it becomes possible to ensure the life-expectancy which is three times as long as the case of the single-layer configuration even when considered simply. At this time, it is assumed that the life-expectancy is defined as a time-interval during which the light-emission luminance is maintained larger than Lt.

Also, it is also possible to perform the switching to the second layer at the predictable point-in-time t1, and further to perform the switching to the third layer at the predictable point-in-time t2 without detecting the light-emission luminance.

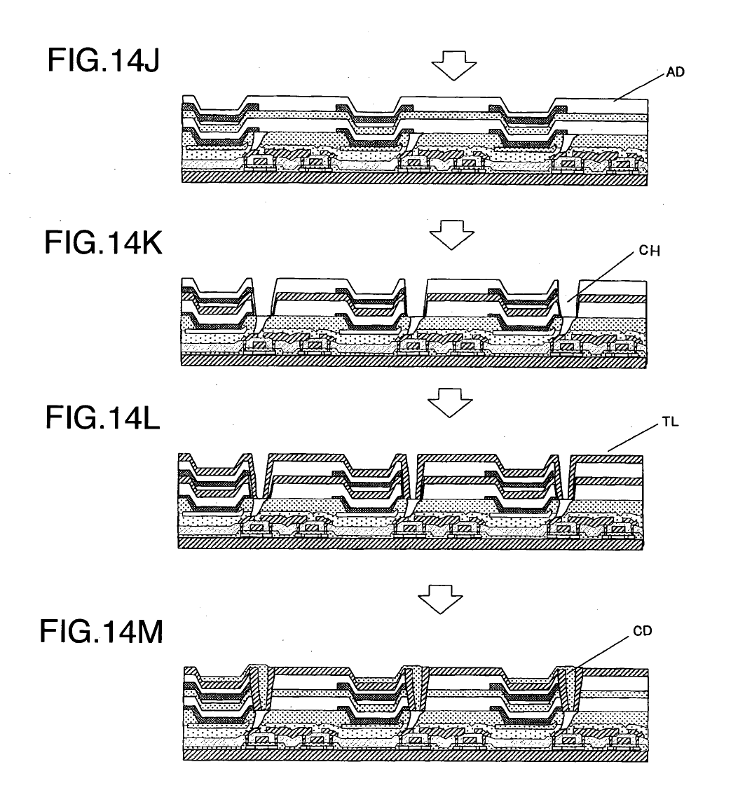

FIG. 13 is a diagram for explaining a configuration example of the system whose long life-expectancy is implemented by switching the multi-layered units. This system corresponds to the one illustrated in FIG. 12, where switching the multi-layered units is performed by switching the gate lines GL. The organic EL display apparatus includes an organic EL panel PNL, a gate-line driving circuit GDR set up in the surroundings, and a data-line driving circuit DDR. This system also includes a time-measuring circuit (i.e., timer) TS. The multi-layered-units switching circuit SW explained in FIG. 12 switches the organic EL element unit from the first layer to the second layer at a point-in-time when the time-measuring circuit TS counts the point-in-time t1 in FIG. 12. Also, the switching circuit SW switches the organic EL element unit from the second layer to the third layer at a point-in-time when the time-measuring circuit TS counts the point-in-time t2 in FIG. 12.

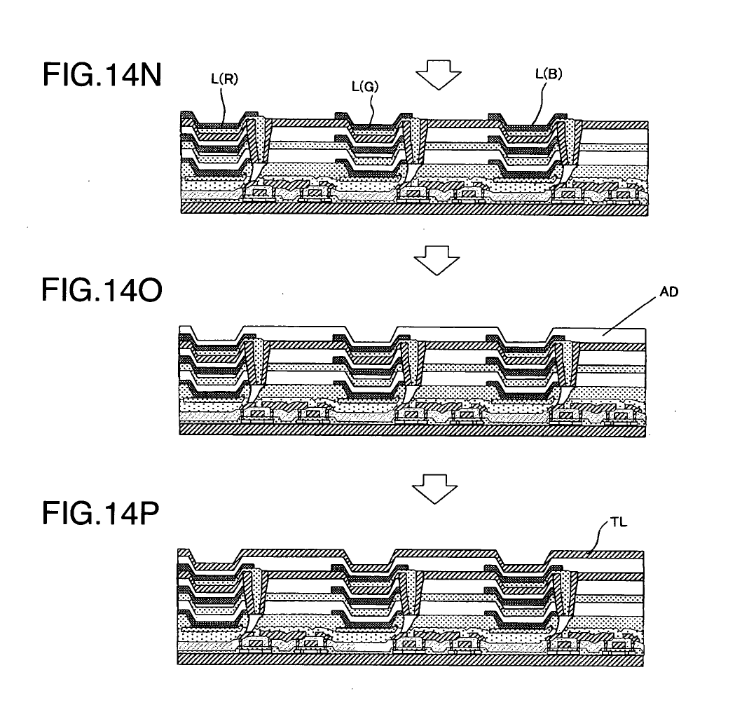

FIG. 14A to FIG. 14P are cross-sectional views corresponding to the A-A′line in FIG. 10 (c) for explaining manufacturing processes for the organic EL display apparatus in FIGS. 10 (a), (b), and (c). The manufacturing processes will be executed in the order of FIG. 14A to FIG. 14P. FIG. 14A illustrates the rear-surface substrate illustrated in FIG. 10 (c). On this rear-surface substrate, the thin-film transistors TFTs are formed on the glass substrate SUB, and patterning for the cathode CD is performed on the protection film PAS, and a cathode contact CDC is formed. The inter-layer insulating film IL is formed on this rear-surface substrate (FIG. 14B). Then, the cathode-CD portion (i.e., the aperture portion of the subpixel) is removed using a photolithography method, and simultaneously a contact hole for the cathode contact CDC is bored (FIG. 14C).

An electrically-conductive member, which is preferably ITO, is provided in such a manner that the electrically-conductive member is buried within the contact hole, thereby forming the cathode contact CDC (FIG. 14D). This cathode contact CDC becomes an electrode for connecting the respective thin-film transistors TFTs to the cathodes of the second-layer and third-layer organic EL element units which will be formed on the upper layers. Next, the first-layer organic EL films L (R), L(G), and L(B) are formed (FIG. 14E). The first-layer organic films L (R), L(G), and L(B) are obtained by evaporating a hole injection layer, a hole transportation layer, a light-emitting layer, and an electron transportation layer in this order. In FIG. 14F, the transparent anode AD is formed on the first-layer organic films L (R), L(G), and L(B). After that, the transparent insulating film TL is formed (FIG. 14G). Next, patterning for the second-layer cathode CD is performed (FIG. 14H). At this time, the second-layer cathode CD is connected to a not-illustrated output electrode of the second-layer-used thin-film transistor. Moreover, the second-layer organic films L (R), L(G), and L(B) are formed in accordance with basically the same processing steps as those in the above-described the first-layer organic films L (R), L(G), and L(B) (FIG. 14I).

The transparent anode AD is formed on the second-layer organic films L (R), L(G), and L(B) (FIG. 14J). After that, a contact hole CH, which attains from this anode AD to the cathode contact CDC in the depth direction, is formed (FIG. 14K). The transparent insulating film TL is formed including the inner wall of this contact hole CH (FIG. 14L). Next, patterning for the cathode CD, which attains to the cathode contact CDC via the contact hole CH, is performed (FIG. 14M).

The third-layer organic films L (R), L(G), and L(B) are formed on this cathode CD (FIG. 14N). Similarly in the above-described respective first-layer and second-layer organic films, the third-layer organic films L (R), L(G), and L(B) are also formed by being multi-layered. The transparent anode AD is formed on the upper layer of the third-layer organic films L (R), L(G), and L(B) (FIG. 14O). Finally, the transparent insulating film TL is formed (FIG. 14P). The execution of a series of manufacturing processes like this allows acquisition of the above-described organic EL display apparatus in the fourth embodiment.

In the above-described configuration of the fourth embodiment, 70-nm MTDATA (4,4′,4″-tris[-N-(-3-methylphenyl)-N-phenylamino]triphenylamine), 10-nm α-NPD, a 60-nm (5%) co-evaporation film of tris (8-hydroxyquinoline) aluminum (Alq)/anthracene, and 60-nm Alq are evaporated as the blue-used organic EL light-emitting layers. Also, 70-nm MTDATA, 10-nm α-NPD, and 60-nm Alq are evaporated as the green-used organic EL light-emitting layers. Also, 70-nm MTDATA, 10-nm α-NPD, and 60-nm Alq/DCJT are evaporated as the red-used organic EL light-emitting layers. Furthermore, a 50-nm-thick silicon nitride SiN film is formed as the insulating film TL.

In the organic EL display apparatus configured using the organic EL panel manufactured in this way, applying a 6-V direct voltage between the cathode and the anode has successfully resulted in acquisition of an 800-cd/m2 or more white luminance.

Also, in the above-described configuration of the fourth embodiment, 70-nm MTDATA, 10-nm α-NPD, a 60-nm (5%) co-evaporation film of tris (8-hydroxyquinoline) aluminum (Alq)/anthracene, and 60-nm Alq are evaporated as the blue-used organic EL light-emitting layers. Also, 70-nm MTDATA, 10-nm α-NPD, and 60-nm Alq/Ir(ppy) are evaporated as the green-used organic EL light-emitting layers. Also, 70-nm MTDATA, 10-nm A-NPD, 60-nm (2%) Alq/DCM2/Ir(ppy), and 60-nm Alq are evaporated as the red-used organic EL light-emitting layers. Furthermore, a 50-nm-thick silicon nitride SiN film is formed as the insulating film TL.

In the organic EL display apparatus configured using the organic EL panel manufactured in this way, applying a 6-V direct voltage between the cathode and the anode has successfully resulted in acquisition of an 800-cd/m2 or more white luminance.

According to the configuration of the above-described embodiment, not by employing the method of prolonging the life-expectancy as the single-layer organic EL element but by combining the short life-expectancy organic EL element units, it becomes possible to prolong the life-expectancy as the organic EL display apparatus as a whole.

### Embodiment 5

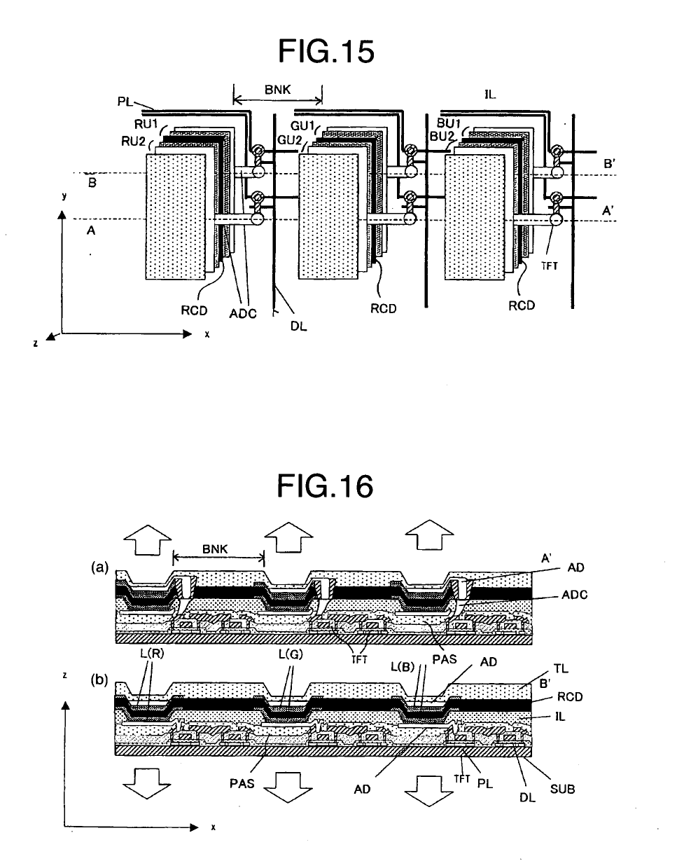

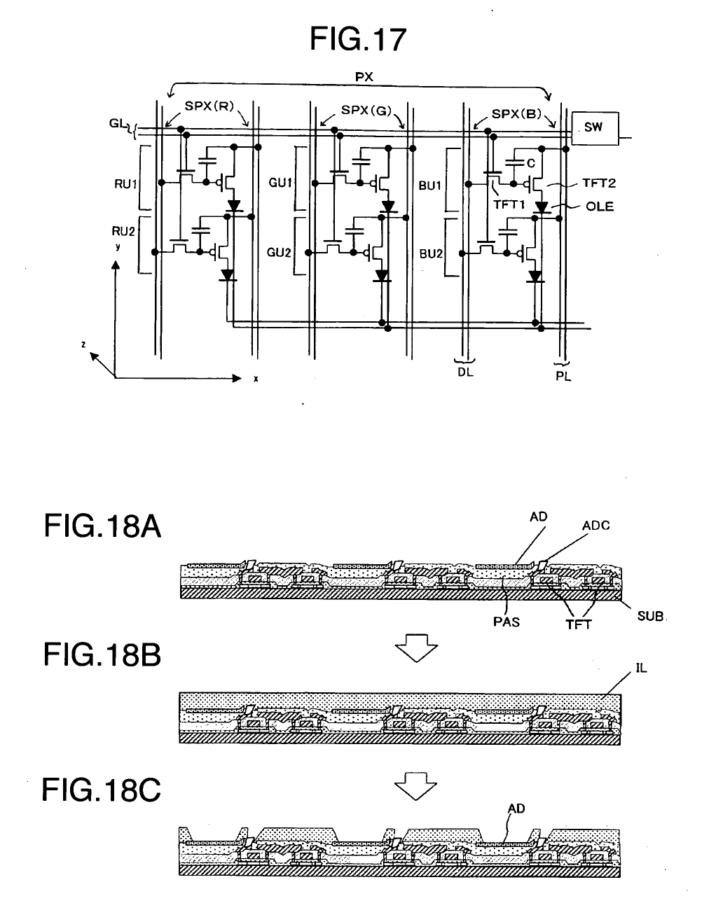

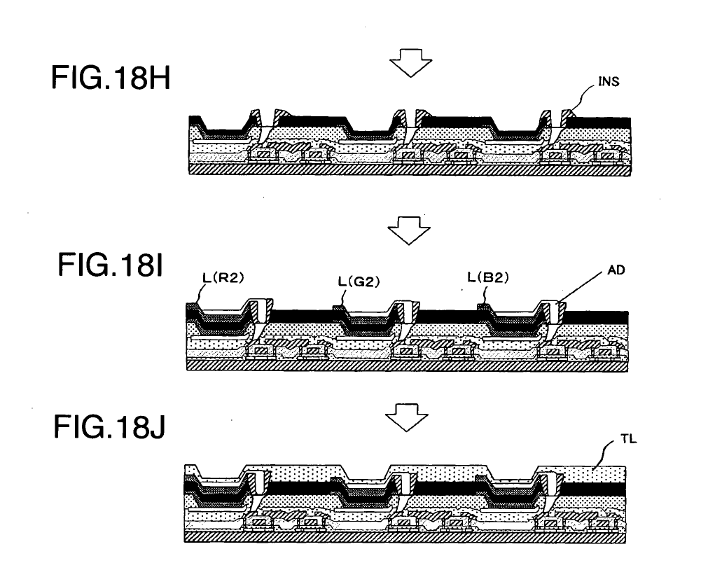

FIG. 18 is a conceptual diagram for explaining a fifth embodiment of the present invention. Also, FIGS. 16 (a) and (b) illustrate cross-sectional views acquired by cutting off the fifth embodiment along an A-A′ line and a B-B′ line in FIG. 15. The fifth embodiment is a double-side organic EL display apparatus where the top-emission organic EL display elements for emitting out display light from the opposite side to the glass substrate SUB as the insulating substrate are multi-layered on the bottom-emission organic EL display elements for emitting out display light to the side of the glass substrate SUB.

In this double-side organic EL display apparatus, on an inter-layer insulating film IL formed on the main surface of the glass substrate SUB, the first-layer red (R) organic EL element unit RU1, the first-layer green (G) organic EL element unit GU1, and the first-layer blue (B) organic EL element unit BU1 are arranged on the surface parallel to the main surface of the glass substrate SUB. Moreover, on these first-layer organic EL element units RU1, GU1, and BU1, the second-layer organic EL element units RU2, GU2, and BU2 are multi-layered.

Namely, the two-layer-structured each-color organic EL element units of the two-layer-structured each-color subpixels are formed within the area of one color main pixel. The first-layer organic EL element units RU1, GU1, and BU1 closer to the glass substrate SUB are the bottom-emission organic EL display elements. The second-layer organic EL element units RU2, GU2, and BU2 multi-layered thereon are the top-emission organic EL display elements.

In FIG. 15, the glass substrate SUB illustrated in FIG. 19 (b) exists in the back of the paper surface. An active pixel circuit where thin-film transistors are used as the active elements is fabricated into the main surface of this glass substrate SUB. The inter-layer insulating film IL is formed in the upper layer of this active pixel circuit.

On the inter-layer insulating film IL, the two-layer-structured red (R), green (G), and blue (B) organic EL element units RU1, RU2, GU1, GU2, and BU1, BU2 are located on the surface parallel to the main surface of the glass substrate SUB. Namely, it turns out that the two-layer-structured each-color subpixels are located within the area of one color main pixel. Furthermore, in the present embodiment, there is provided a driving circuit for driving the two-layer-structured each-color organic EL element units.

FIG. 15 and FIGS. 16 (a) and (b) illustrate the three each-color subpixels which configure one full-color main pixel. A bank referred to as “bank” is provided between the respective subpixels. This bank BNK is utilized for the area limitation in a formation process of forming organic films of each organic EL element, especially in a formation process of forming the light-emitting layers. The area of this bank is not utilized for the display. The thin-film transistors TFTs or the like which configure the above-described active pixel circuit are formed in the portion hidden by this bank BNK.

The thin-film transistors TFTs are connected to a signal wiring DL, a power-supply wiring PL, and a scanning wiring (not illustrated). One thin-film transistor TFT is illustrated for each organic EL element in FIG. 15, and two thin-film transistors TFTs are illustrated for each organic EL element in FIGS. 16 (a) and (b). The details, however, will be explained later. Incidentally, an anode AD, i.e., one electrode of the organic EL element unit of each layer, is connected to each thin-film transistor TFT via an anode contact ADC.

In FIGS. 16 (a) and (b), the first-layer organic EL element units RU1, GU1, and BU1 on the inter-layer insulating film IL, i.e., the first-layer red (R), green (G), and blue (B) subpixels, are formed directly above the anode AD formed by removing a part of the inter-layer insulating film IL in a pixel portion of each-color subpixels. Here, the first-layer organic EL element units RU1, GU1, and BU1 include first-layer light-emitting layers L (R), L(G), and L(B) including an organic film, and a reflection cathode RCD.

On the upper layer of the reflection cathode RCD configuring the first-layer organic EL element units RU1, GU1, and BU1, the second-layer organic EL element units RU2, GU2, and BU2 are multi-layered. Here, the second-layer organic EL element units RU2, GU2, and BU2 include second-layer light-emitting layers L (R), L(G), and L(B) and a transparent anode AD. A transparent insulating film TL is formed in the uppermost layer.

In the present embodiment, the reflection cathode RCD configuring the first-layer organic EL element units RU1, GU1, and BU1 is put into co-use as a reflection cathode of the second-layer organic EL element units RU2, GU2, and BU2. This co-use makes it possible to accomplish thin-type implementation of the entire double-side organic EL display apparatus. The present invention, however, does not exclude a configuration where the first-layer reflection cathode and the second-layer reflection cathode are set up as mutually different electrodes.

The anodes AD of the respective organic EL element units RU2, GU2, and BU2 illustrated in FIG. 15 are each connected to its own thin-film transistor TFT in the following manner: Namely, as illustrated in the A-A′ cross section in FIG. 16 (a), the first-layer anode AD, which is the most proximate to the insulating substrate SUB, is electrically connected to an output electrode of the thin-film transistor TFT via a contact hole which is bored in a protection film (i.e., passivation film) PAS of the thin-film transistor formation layer.

Similarly, as illustrated in the B-B′ cross section in FIG. 16 (b), the second-layer anode AD is electrically connected to an output electrode of the thin-film transistor TFT via the contact hole which is bored in the passivation film PAS, the inter-layer insulating film IL, the first-layer light-emitting layers, and the insulating film TL.

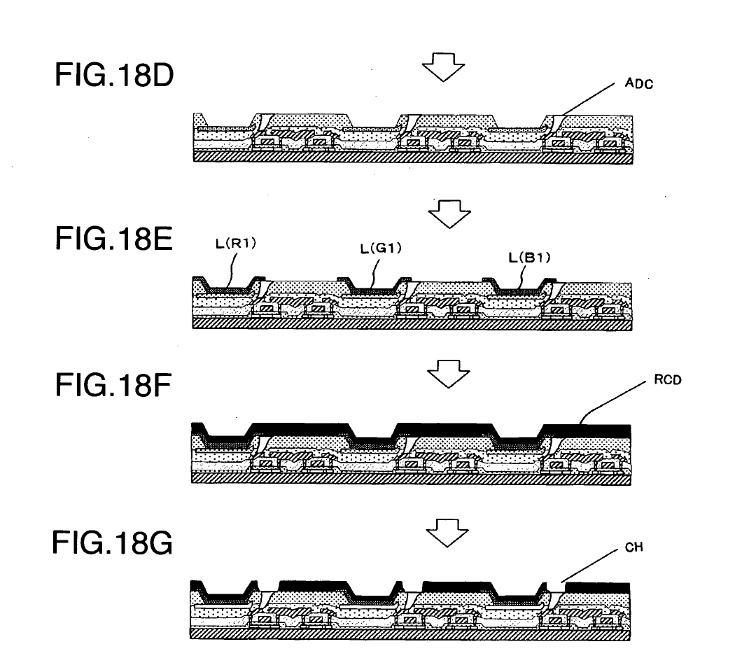

FIG. 17 is an explanatory diagram for explaining an example of the equivalent circuit to the pixel of the organic EL display apparatus of the present invention. In FIG. 17, a notation PX denotes one color main pixel. Each color main pixel PX includes three color subpixels SPX(R), SPX(G), and SPX(B) which are arranged in the right-to-left (i.e., x) direction in FIG. 17. The red subpixel SPX(R) includes the units RU1 and RU2 which are multi-layered in the direction (i.e., z direction) perpendicular to the paper surface in FIG. 17. Similarly, the green subpixel SPX(G) includes the units GU1 and GU2 which are multi-layered in the z direction. The blue subpixel SPX(B) includes the units BU1 and BU2 which are multi-layered in the z direction. The units RU1, GU1, and BU1 are the bottom-emission organic EL display elements, and the units RU2, GU2, and BU2 are the top-emission organic EL display elements.

Each-color unit is represented by an equivalent circuit including two thin-film transistors TFT 1 and TFT 2, a capacitor C, and an organic EL light-emitting unit OLE. Also, in FIG. 20, two wirings GL extending in the right-to-left direction (i.e., x) in FIG. 20 are scanning-signal lines (gate lines). Two wirings DL extending in the up-and-down (i.e., y) direction are display-signal lines (data lines). Two wirings PL similarly extending in the up-and-down direction are power-supply lines (current-supply lines). Each of these lines is provided for each unit which configures each-color subpixel.

Incidentally, in FIG. 15, only the second thin-film transistor TFT 2 in FIG. 17 has been illustrated as the TFT. Also, the configuration illustrated in FIG. 17 is the basic circuit configuration. Accordingly, as the driving circuit for the organic EL display apparatus of the present invention, various types of configurations exist other than this basic configuration.

Also, in the present embodiment, a switching circuit SW for switching the first-layer and second-layer organic EL element units is provided on the gate lines GL. Different display data are each supplied to the first-layer and second-layer organic EL element units, thereby allowing implementation of the different displays on each of the double sides. Incidentally, the same display data is supplied to the two data lines DL, thereby allowing implementation of the same display on each of the double sides.

The use of the switching circuit SW allows selection of the first-layer and second-layer organic EL element units, thereby making it possible to select and light up only one of the two-layer-structured each-color organic EL element units.

According to the present embodiment, it becomes possible to provide a thin-type and light-weighted double-side organic EL display apparatus which is capable of displaying different data or the same data on the front-and-back double sides. When causing the same data to be displayed on the front-and-back double sides, the two data lines DL and the two current-supply lines PL are connected in common at the supply points. Also, switching the two-layer-structured each-color organic EL element units is not limited to the switching using the gate lines GL. Namely, the switching may also be performed using the data lines DL and the current-supply lines PL. Otherwise, the switching can also be performed by combining the gate lines GL, the data lines DL, and the current-supply lines PL.

FIG. 18A to FIG. 18J are cross-sectional views corresponding to the A-A′line in FIG. 16 (a) for explaining manufacturing processes for the double-side organic EL display apparatus explained in FIG. 15 and FIGS. 16 (a) and (b). The manufacturing processes will be executed in the order of FIG. 18A to FIG. 18J. FIG. 18A illustrates the rear-surface substrate illustrated in FIG. 16 (b). On this rear-surface substrate, the thin-film transistors TFTs are formed on the glass substrate SUB, and patterning for the anode AD is performed on the protection film PAS, and an anode contact ADC is formed. The inter-layer insulating film IL is formed on this rear-surface substrate (FIG. 18B). Then, the anode-AD portion (i.e., the aperture portion of the subpixel) is removed using a photolithography method, and simultaneously a contact hole for the anode contact ADC is bored (FIG. 18C).

An electrically-conductive member, which is preferably ITO, is provided in such a manner that the electrically-conductive member is buried within the bored contact hole, thereby forming the anode contact ADC (FIG. 18D). This anode contact ADC becomes an electrode for connecting the respective thin-film transistors TFTs to the anodes of the second-layer organic EL element units which will be formed on the upper layers. Next, the first-layer organic EL films L (R1), L(G1), and L(B1) are formed (FIG. 18E). The first-layer organic films L (R1), L(G1), and L(B1) are obtained by evaporating a hole injection layer, a hole transportation layer, a light-emitting layer, and an electron transportation layer in this order. In FIG. 18F, the reflection cathode RCD is formed on the first-layer organic films L (R1), L(G1), and L(B1). After that, a contact hole CH is formed in the reflection cathode RCD (FIG. 18G).

An insulating layer INS for performing insulation between the reflection cathode RCD and an anode which will be described layer is formed on the portion of this contact hole CH (FIG. 18H). Moreover, the second-layer organic films L (R2), L(G2), and L(B2) are formed in accordance with basically the same processing steps as those in the above-described the first-layer organic films. Furthermore, the aperture portion of the subpixel including each of the second-layer organic films L (R2), L(G2), and L(B2) and the transparent anode AD connected to the thin-film transistors via the contact hole CH are formed on the second-layer organic films L (R2), L(G2), and L(B2) (FIG. 18I).

Finally, the transparent insulating film TL is formed (FIG. 18J). The execution of a series of manufacturing processes like this allows acquisition of the above-described double-side organic EL display apparatus in the fifth embodiment.

In the above-described configuration of the fifth embodiment, 70-nm MTDATA (4,4′,4″-tris[-N-(-3-methylphenyl)-N-phenylamino]triphenylamine), 10-nm α-NPD, a 60-nm (5%) co-evaporation film of tris (8-hydroxyquinoline) aluminum (Alq)/anthracene, and 60-nm Alq are evaporated as the blue-used organic EL light-emitting layers. Also, 70-nm MTDATA, 10-nm α-NPD, and 60-nm Alq are evaporated as the green-used organic EL light-emitting layers. Also, 70-nm MTDATA, 10-nm α-NPD, 60-nm (2%) Alq/DCJT, and 60-nm Alq are evaporated as the red-used organic EL light-emitting layers. Also, 70-nm Al is evaporated as the reflection-cathode material. After that, the organic films are formed in the reverse order to the one in the above-described evaporations, and ITO is formed as the transparent anode. Finally, a 50-nm-thick silicon nitride SiN is formed as the transparent insulating film TL. Incidentally, a sealing plate such as the transparent glass substrate can be located such that the sealing plate covers the silicon nitride SiN.

In the double-side organic EL display apparatus configured using the organic EL panel manufactured in this way, applying a 6-V direct voltage between each cathode and each anode has successfully resulted in acquisition of an 800-cd/m2 or more white luminance on each of the double sides.

In the above-described configuration of the fifth embodiment, 70-nm MTDATA, 10-nm α-NPD, a 60-nm (5%) co-evaporation film of tris (8-hydroxyquinoline) aluminum (Alq)/anthracene, and 60-nm Alq are evaporated as the blue-used organic EL light-emitting layers. Also, 70-nm MTDATA, 10-nm α-NPD, and 60-nm (5%) Alq/Ir(ppy) are evaporated as the green-used organic EL light-emitting layers. Also, 70-nm MTDATA, 10-nm α-NPD, 60-nm (2%) Alq/DCM2/Ir(ppy), and 60-nm Alq are evaporated as the red-used organic EL light-emitting layers. Also, 70-nm Al is evaporated as the reflection-cathode material. Finally, a 50-nm-thick silicon nitride SiN is formed as the transparent insulating film TL. Incidentally, a sealing plate such as the transparent glass substrate can be located such that the sealing plate covers the silicon nitride SiN.

In the double-side organic EL display apparatus configured using the organic EL panel manufactured in this way, applying a 6-V direct voltage between each cathode and each anode has successfully resulted in acquisition of an 800-cd/m2 or more white luminance on each of the double sides.

According to the configuration of the above-described embodiment, it becomes possible to provide a double-side organic EL display apparatus which allows accomplishment of the thin-type implementation and light-weight implementation thereof.

It should be further understood by those skilled in the art that although the foregoing description has been made on embodiments of the invention, the invention is not limited thereto and various changes and modifications may be made without departing from the spirit of the invention and the scope of the appended claims.

1. An organic EL display apparatus, comprising:
first organic EL elements formed on a main surface of an insulating substrate, and
second organic EL elements formed by being multi-layered on said first organic EL elements, wherein
electric currents are controlled by first active elements and second active elements which are different active elements from each other, said electric currents being caused to flow in order to drive said first organic EL elements and said second organic EL elements.

2. The organic EL display apparatus according to claim 1, wherein
said first active elements and said second active elements are formed between said first organic EL elements and said insulating substrate,
said first organic EL elements and said first active elements being electrically connected to each other via first contact holes, said second organic EL elements and said second active elements being electrically connected to each other via second contact holes.

3. The organic EL display apparatus according to claim 2, wherein
said second contact holes for connecting said second organic EL elements and said second active elements to each other are located on side-surface sides of said first organic EL elements via insulating films.

4. The organic EL display apparatus according to claim 2, wherein
said first and second contact holes are located within the same unit pixel.

5. The organic EL display apparatus according to claim 1, wherein
said organic EL elements belonging to the same layer of said organic EL elements formed by being multi-layered on each other include light-emitting layers formed of the same material.

6. The organic EL display apparatus according to claim 5, wherein
said light-emitting layers exist all over unit pixels widely in a flat-plane-like manner.

7. The organic EL display apparatus according to claim 5, wherein
a plurality of unit pixels configure one main pixel in said organic EL elements, said plurality of unit pixels being adjacent to each other in said multi-layered direction,
said light-emitting layers being changed in said unit pixels which configure said main pixel.

8. The organic EL display apparatus according to claim 7, further comprising
a third organic EL element on each of said second organic EL elements, and wherein
said first to said third organic EL elements which are multi-layered on each other configure said one main pixel.

9. The organic EL display apparatus according to claim 1, wherein
said organic EL elements belonging to the same layer of said organic EL elements formed by being multi-layered on each other include light-emitting layers formed of different materials.

10. The organic EL display apparatus according to claim 9, wherein
a plurality of unit pixels configure one main pixel, said plurality of unit pixels being adjacent to each other in said flat-plane direction.

11. An organic EL display apparatus, comprising:
an insulating substrate,
a first organic EL element formed on said insulating substrate, and
a second organic EL element formed on said first organic EL element,
light emission of said first organic EL element being emitted out to said insulating-substrate side, light emission of said second organic EL element being emitted out to an opposite side to said insulating-substrate side, wherein
said first organic EL element has a configuration formed by multi-layering a first transparent electrode, a first organic light-emitting layer, and a first reflection electrode sequentially from the most proximate side to said insulating substrate,
said second organic EL element having a configuration formed by multi-layering a second reflection electrode, a second organic light-emitting layer, and a second transparent electrode sequentially from the most proximate side to said insulating substrate,
active elements for driving said first organic EL element and said second organic EL element being provided between said insulating substrate and said first organic EL element.

12. The organic EL display apparatus according to claim 11, wherein
said second transparent electrode of said second organic EL element and said active element for driving said second organic EL element are connected to each other via a contact hole, said contact hole being located by penetrating an insulating film provided at an end portion of said first organic EL element.

13. The organic EL display apparatus according to claim 11 or 12, wherein
said first reflection electrode of said first organic EL element and said second reflection electrode of said second organic EL element are configured using one double-side reflection electrode which plays a role of said two reflection electrodes.

14. An organic EL display apparatus, comprising:
an insulating substrate,
an active element formed on said insulating substrate,
a first transparent electrode connected to said active element and separated for each color subpixel,
a first light-emitting layer separated for each color subpixel,
a double-side reflection electrode separated for each color subpixel,
a second light-emitting layer separated for each color subpixel, and
a second transparent electrode separated for each color subpixel,
said insulating substrate, said active element, said first transparent electrode, said first light-emitting layer, said double-side reflection electrode, said second light-emitting layer, and said second transparent electrode being multi-layered in this order, wherein
said double-side reflection electrode has an aperture portion for each color subpixel,
said active element and said second transparent electrode being electrically connected to each other via a contact hole which passes through said aperture portion of said double-side reflection electrode.

15. The organic EL display apparatus according to claim 14, wherein
said first organic EL element or said second organic EL element is one of said subpixels which configure one color main pixel, and
said plurality of first organic EL elements or second organic EL elements respectively configure said one color main pixel on upper and lower layers of said double-side reflection electrode,
said plurality of first organic EL elements or second organic EL elements being adjacent to each other on said insulating substrate and in a direction parallel to said insulating-substrate surface.

16. The organic EL display apparatus according to claim 14 or 15, wherein
said double-side reflection electrode is located in such a manner that said double-side reflection electrode is overlapped on said first transparent electrode configuring said first organic EL element and said second transparent electrode configuring said second organic EL element,
said double-side reflection electrode having said aperture portion for each subpixel which includes said first organic EL element and said second organic EL element, said contact hole passing through said aperture portion.
